(19) United States
(12) Patent Application Publication
(10) Pub. No.: US 2008/0213477 A1
(43) Pub. Date: Sep. 4, 2008

(54) INLINE VACUUM PROCESSING APPARATUS AND METHOD FOR PROCESSING SUBSTRATES THEREIN

(76) Inventors: Arno Zindel, Maienfeld (CH); Markus Poppeller, Feldkirch (AT); Dmitry Zimin, Hedingen (CH); Hansjorg Kuhn, Chur (CH); Jorg Kerschbaumer, Feldkirch (AT)

Correspondence Address: PEARNE & GORDON LLP, 1801 EAST 9TH STREET, SUITE 1200, CLEVELAND, OH, 44114-3108, US

(21) Appl. No.: 12/040,292

(22) Filed: Feb. 29, 2008

Related U.S. Application Data
(60) Provisional application No. 60/892,689, filed on Mar. 2, 2007.

(51) Int. Cl. C23C 16/00

(52) U.S. Cl. 427/255.28; 118/719

(57) ABSTRACT

An inline vacuum processing apparatus for processing of substrates in vacuum comprises at least one load-lock chamber, at least two subsequent deposition chambers to be operated with essentially the same set of coating parameters and at least one unload-lock chamber plus means for transferring, post-processing and/or handling substrates through and in the various chambers. A method for depositing a thin film on a substrate in such processing system comprises the steps of introducing a first substrate into a load-lock chamber, lowering the pressure in said chamber; transferring the substrate into a first deposition chamber; depositing a layer of a first material on said first substrate using a first set of coating parameters; transferring said first substrate into a second, subsequent deposition chamber of said inline system without breaking vacuum and depositing a further layer of said first material on said first substrate using substantially the same set of parameters. Simultaneously to step f) a second substrate is being treated in said inline vacuum system according to step d).

The present invention relates to an apparatus for the vacuum processing of substrates, especially large area substrates with sizes of 1 m² or more, following the so-called inline concept. In a preferred embodiment it describes a system for chemical vapour deposition (CVD) of zinc oxide (ZnO) layers for thin film solar cells, e. g. for front and back contact layers in the field of solar cells, especially silicon based solar cells such as thin film solar cells. Furtheron it may be used for all applications in large area coating where chemical vapour deposition is applied.

### DEFINITIONS

System, apparatus, processing equipment, device are terms used in this disclosure interchangeably for at least an embodiment of the invention.

“Processing” in the sense of this invention includes any chemical, physical or mechanical effect acting on the substrates. Substrates in the sense of this invention are components, parts or workpieces to be treated in an inventive vacuum processing apparatus.

Substrates include, but are not limited to flat, plate shaped parts having rectangular, square or circular shape. In a preferred embodiment, this invention adresses essentially planar substrates of a size >1 m² such as thin glass plates.

CVD Chemical Vapour Deposition is a well known technology allowing the depostion of layers on heated substrates. A usually liquid or gaseous precursor material is being fed to a process system where a thermal reaction of said precursor results in deposition of said layer. LPCVD is a common term for low pressure CVD.

DEZ—diethyl zinc is a precursor material for the production of TCO layers in vacuum processing equipment.

TCO or TCO layers are transparent conductive layers.

The terms layer, coating, deposit and film are interchangeably used in this disclosure for a film deposited in vacuum processing equipment, be it CVD, LPCVD, plasma enhanced CVD (PECVD) or PVD (physical vapor deposition).

A solar cell or photovoltaic cell is a electrical component, capable of transforming light (essentially sun light) directly into electrical energy by means of the photoelectric effect.

### BACKGROUND OF THE INVENTION

Inline vacuum processing systems are well known in the art. U.S. Pat. No. 4,358,472 or EP 0 575 055 show systems of that kind. In general terms such a system comprises an elongated transport path for substrates in a vacuum environment. Along said transport path various processing means may be employed, such as heating, cooling, deposition (PVD, CVD, PECVD, . . . ) , etching or control means-acting on said subtrates. If cross-contamination of such processes has to be avoided, advantageously valves or gates are being used to separate certain segments from each other. Such valves will allow the passing of substrates from one of said segments to another and will be closed during the processing in a segment. Usually such segments are called process stations or process modules (PM). If discrete substrates such as wafers, glass sheets, plastic substrates are being used, processing may take place continously or discontinously. In the first case, substrates will pass by the processing means (such as lamps, coolers, deposition sources, . . . ) during processing, in the latter the substrates will be held in a fixed position during processing. The transport through the system can take place in many ways such as: rollers, belt drives or linear motor systems (e. g. U.S. Pat. No. 5,170,714). The orientation of the substrates may be vertical or horizontal or inclined to a certain degree. In many applications it is advantageous to place the substrates in carriers for the time of the transport.

The transport path may be linear (one way) or two-fold linear (back and forth on the same way) or in the alternative with a separate return path. The arrangement of said forth and return path may be next to each other or in a stacked arrangement one above the other as e. g. shown in U.S. Pat. No. 5,658,114.

Advantageously for loading and unloading as well as for entering/exiting the vacuum environment a separate load/unload station may be provided (“load lock”). This way entering/exiting the transport path in vacuum may take place without affecting the vacuum conditions in the process chambers.

In this basic description no reference was made to further necessary equipment like pumps, electric and water supply, exhaust, gas supply, controls and so forth as one skilled in the art would know to be required.

Due to economic requirements it is important to coat large area substrates. In particular this is important in the solar and display industry. Therefore such inline systems are being used to process substrates in a chain, sequentially transported from process station to process station. In a system with n processing stations n substrates can be treated/processed at once, with the processing time of the slowest station (in terms of processing time) determining the throughput of the system.

In the PV (photo voltaic) industry as well as in the display industry, TCO layers are used for solar cells and TFT (thin film transistor) applications. ITO (indium tin oxide) or ZnO (zinc oxide) are widely used. ZnO layers, however, show premium performance as a conductive contacting material for solar cell applications. Solar cells traditionally have been manufactured based on semiconductor wafers. The increasing demand for silicon wafers however has increased the demand for so called thin film solar cells based on glass, metal or plastic, where thin layers of silicon, p- or n-doped silicon and TCO layers for the active part are deposited. As mentioned above, large substrates can be manufactured more economically than wafer, provided that certain homogeneity of layer deposition can be obtained. Previous experiments have been largely carried out on rather small substrate sizes. The ZnO layers (and the silicon layers) applied for thin film solar cell applications need to be patterned in order to allow serial switching of individual cells. Such cell separation (called “scribing”) is normally achieved by a laser system. Laser ablation of material to a certain depth along predefined lines or patterns results in certain regions of the coated substrate to be electrically insulated from others. It will be readily understood that reliably uniform layer properties over the whole substrate range are essential for the performance and efficiency of the thin film solar cell. Variations in substrate thickness or layer thickness would result in not fully scribed lines or scribing of the substrate.

Another factor in commercial manufacturing of solar cells or displays is the throughput of the processing equipment used. Basically the time for the transport of substrates in a system has to be minimized to allow high throughput at a given deposition rate. Things get even worse due to the need for heating up the substrates before deposition in most applications. In a system design comprising just one chamber for load/unload, heating, deposition most of the reactor utilization time is used for heating up substrates and transport. Therefore single chamber approaches, although simple and easy to manufacture, are less favoured due to said economic disadvantages.

It is therefore the purpose of the present invention to propose an inline vacuum processing system avoiding the disadvantages known on the art and moreover allowing to perform an economic vacuum processing of substrates therein.

### SHORT DESCRIPTION OF THE DRAWINGS

FIG. 1 shows a cross section of an inline vacuum processing system according to the invention.

FIG. 2 shows an infrared heater array used in the inventive processing system

FIG. 3 shows a schematic drawing of a reactor/Process module PM according to the invention

FIG. 4 depicts in more detail the gas dosing part of a process module

FIG. 5 shows a hot table 53 with a border element 51. FIG. 5b) shows a variant of said border element.

### SOLUTION ACCORDING TO THE INVENTION

A method for depositing a thin film on a substrate in an inline vacuum processing system according to the invention comprises the steps of a) introducing a first substrate into a load-lock chamber; b) lowering the pressure in said chamber; c) transferring said first substrate into a first deposition chamber; d) depositing a layer of a first material at least partially on said first substrate using a first set of coating parameters; e) transferring said first substrate into a second, subsequent deposition chamber of said inline system without breaking vacuum ; f) depositing a further layer of said first material at least partially on said first substrate using substantially the same set of parameters ; g) transferring said first substrate into a load lock chamber; h) removing said first substrate from said system-wherein simultaneously to step f) a second substrate is being treated in said inline vacuum system according to step d).

An apparatus for inline vacuum processing of substrates comprises at least one one load-lock chamber, at least two deposition chambers to be operated with essentially the same set of coating parameters; at least one unload-lock chamber and means for transferring, post-processing and/or handling substrates through and in the various chambers.

### DETAILED DESCRIPTION OF THE INVENTION

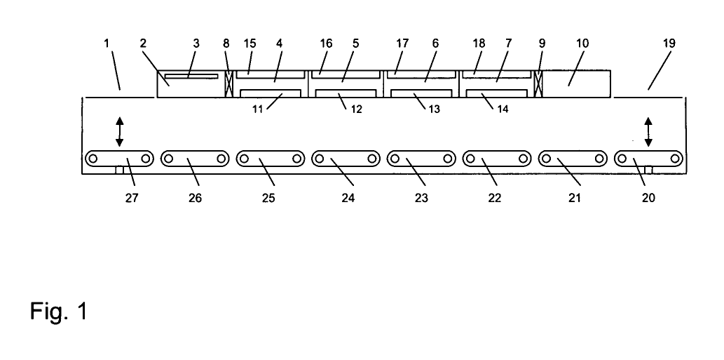

FIG. 1 is showing an embodiment of the present invention with 4 PM (process modules), although other configurations with at least 2 PMs are economically feasible. The substrates, preferably glasses, with a thickness in the range between 3 and 4 mm are fed individually into a loading station 1 of the inline system. This station allows the safe handing over from e. g. a handling system (robot) to the inline system, e. g. into a carrier. From the loading station 1 substrates are transported by a conveyor belt system (not shown) into the load lock 2, where the transport is accomplished by rollers.

Within the load lock 2 the pressure is lowered by means of vacuum pumps (not shown) to a level allowing further transfer of the substrates. Simultaneously the substrates are being heated up by an array of infrared heaters 3. As soon as the transfer pressure and the desired substrate temperature are reached the substrates will wait in the load lock until ongoing processing in the subsequent process modules 4-7 has been finished. After decontamination (cleaning, usually by means of a etching gas) of the process modules and subsequent pump down to transfer pressure of approximately 0.1 mbar the gate valves 8 between the “load lock in” 3 and PM 4 and the gate valve 9 between PM 7 and “load lock out” 10 open and the substrates are transported by rollers through the system till they reach their (next) position indicated by a laser barrier. The substrate in PM 7 will enter load lock out 10, the substrate formerly processed in PM 4 will be positioned in PM 5 and so forth.

In the PMs 4-7 the substrates are being positioned over a hot plate/substrate holder 11-14 still resting on the transport rollers. The substrate holders show vertically retractable and extendable pins, which extend through the hot plate. Said pins will move upward and lift the substrate from the transporting roller system. The transport rollers 36 (see FIG. 3) will then be retracked sideways from the substrate bottom. Then the substrate can be positioned on the substrate holder 11-14 or 35 respectively by lowering the pins. For removing the substrate from the PM the described sequence will performed in reverser order.

In one embodiment of the invention 12-16 pins will be installed to allow a good weight distribution of a substrate having 1100 m×1300 mm. The pins may be made from stainless steel, with a diameter of 6 mm, being guided in bushings inserted in the hot table/substrate holder 11-14. Advantageously the tip of the pins may be provided with a plastic cap (e. g. Selasol) in order to avoid damage of the substrate. Number and mechanical properties of said pins may be adjusted depending on the specifications.

In one embidment the pins are being actuated by a common lifting meachnism, like a hydraulic or pneumatic cylinder or a respective motor installed in the bottom of the PM below the hot table. The pins are resting on a plate; e. g. made from steel and are being moved up and down by said common lifting mechanism. In order to avoid the pins to get jammed in the bushings, they are advanteously not fixedly connected with, but simply rest on said plate. In order to nevertheless exert an additional pulling force on said pins during moving down, permanent magnets may be incorprated in said plate interacting with said pin. The latter is for this application made from ferritic steel or shows an iron insert.

The above mentioned heated substrate holders 11-14 may be designed to allow different heating conditions (such as substrate temperature, heat up times and homogeneity of subtrate temperature) in order to perform different processes in said process modules 4-7. The substrate holder/hot plate 11-14 will advantageously allow the substrate to be contacted over its complete surface to allow good heat transfer. A further preferred embodiment of a hot plate is being shown in FIG. 5. The hot plate 53 has an area for the substrate 50 to be placed upon. The edge region of said bearing area exhibits a shoulder comprising a border element 51. This border element rests in a recess of the hot plate 53. It is designed in such a way that the substrate partially overlaps border element 51 allowing heat transfer but has at the same time a region which is not affected by the substrate 50. Advantageously a small gab of 0.5 mm is provided between substrate 50 and border element 51, so that no direct contact exists. As a result, the border element 51 has a shape comparable to a frame to the substrate. The border element further comprises a heating element 52 which can be electric heating element incorporated in a pocket. The advantages of said border element are as follows:
The separate heating element 52 allows separate control of temperature at the edge regions of the substrate. It allows compensation of increased heat transfer at the edges (radiation losses).
During a deposition process not only substrate 50, but also border element 51 and hot plate 53 will be coated and need to be cleaned. Due to the nature of the coating process, border element 51 will be more affected than other regions. Due to reduced size, the border element 51 can be exchanged more easily than the whole hot table 53.
The small gap between border element 51 and substrate 50 avoids that a continuous coating at the edge region comes into existence.
During deposition the coating process will be conducted with a surplus of deposition gases. This unused waste gas has to be evacuated via the vacuum pumps. The waste gas tends to react with regions in the exhaust systems and the pumps itself, gradually coating them and thereby creating need for maintenance. The regions of the border element 51 not used for heat transfer to the substrate 50 however will have a getter effect (attracting such unused gases). Due to the facilitated exchange the border element 51 will allow to reduce the downtime of the whole system.

The design of the border element 51 can be as displayed in cross section in FIG. 5. FIG. 5b shows an alternative design with a ridge 54. Advantageously the height of said ridge is chosen to be the same as the thickness of the substrate, but may vary, if necessary.

An inventive process may start by dosing working gases such as diborane and DEZ to the process chamber through a gas shower system 15-18. Each of the process chambers 4-7 will be equipped with an individual gas shower system, but several or all gas showers 15-18 may be supplied by the same gas dosing and mixing system (not shown in FIG. 1).

According to an inventive method for processing substrates in an inline system as described above, the deposition of a layer is accomplished by the mixing of Dietyhl zinc (DEZ) and water in the gas phase in a pressure range between 0.3 mbar and 1.3 mbar. Films are formed preferably on hot surfaces where the growth rate is a function of the temperature and the availability of gas. One goal in the deposition of ZnO layers is to enhance their conductivity. Diborane (B₂H₆) is added to the reaction mixture forcing a doping of the Transparent Conductive Oxide (TCO) layer.

Due to the design of the inventive inline system the layer can be deposited in n steps with 1/n layer thickness each so that the total thickness is reached after the respective number of PM's has been passed. A further advantage of these PM's with comparable processing properties (all gas showers are supplied by the same gas delivery system, equal or comparable processing times, comparable pressure and gas flow) it is not necessary to separate the PM's from each other by gate valves or alike since cross contamination is no problem. Basically they form a chain of deposition chambers with individual heater plates where in each case a part of the deposition is done.

After accomplishing all deposition steps the substrate will be transferred to the load lock out 10 through a gate valve 9 on a roller system. There the substrate will be brought to atmospheric pressure while performing a (first) cool down. As soon as the load lock out 10 reached atmospheric pressure the substrates are transferred to the unload unit 19 by a roller system in the load lock 10 and a conveyor belt system on the unload unit 19.

Now the substrate is transferred to the return track level by a lifting device 20 within the unloading unit 19. The return track may comprise several conveyor belt units 21-26 operating independently and transferring the substrate step by step to the loading table 1.

Alternatively a single conveyor may be employed. The step by step motion described allows keeping the glass substrates as long as possible in the protected environment of the system and allowing the cool down of the substrates to a transfer temperature. This temperature is determined by the maximum temperature allowed by the external handling system which is used to store and transport substrates to and from the equipment. The loading stations itself is equipped with a lifting device 27 which allows bringing back the substrate from the return track level to the transport or deposition level where the substrates are finally picked up by the external loading system (not shown).

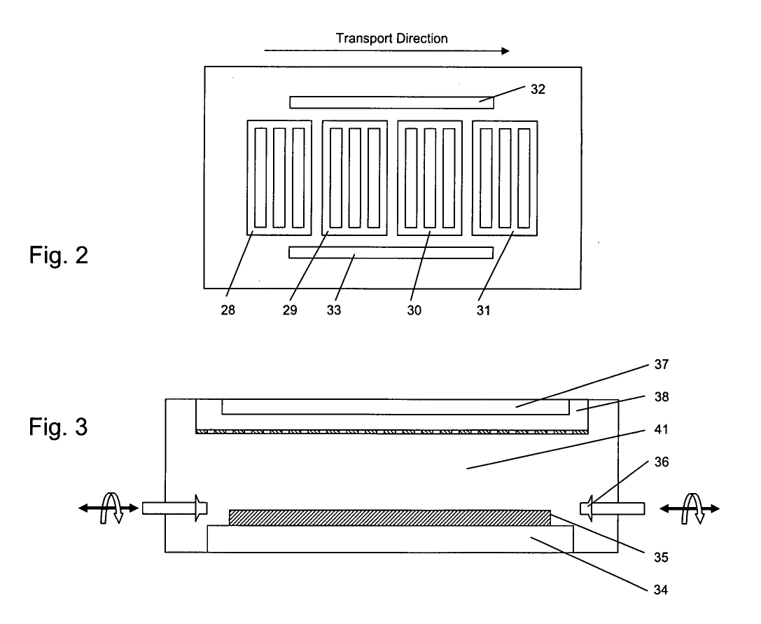

In a preferred embodiment 4 deposition chambers (PM) are used. All hot plates 11-14 are nearly at the same temperature setting between 160 and 200° C., perfereably at 180° C. The heater array in the load lock in 3 has heated the substrates slightly above said intended deposition temperature of about 175° C. to compensate for heat losses during transfer. It has also been shown that non uniform heating within the load lock system is beneficial. The edge regions of the glass are heated to a temperature about 10° C. higher than the center portion. However, this temperature gradient depends on the transfer speed of the glasses to the first hot plate 11. FIG. 2 shows a typical infrared heater array used in the load lock system. It is splitted into e. g. 6 independent heater zones 28-33 (28-31 arranged crosswise, 32 and 33 lengthwise), where each array's temperature is controlled by an infrared pyrometer measuring the substrates temperature. For cost saving reasons some heater arrays may be bundled and use only a single control pyrometer. For example zone 29 and zone 30 are generating the center temperature of the glass substrate while zone 31 and 30 will generate one part of the edge portions and 28 and 32 the other portion. For uniformity improvement it is also beneficial to move the substrate forward and back slightly in transport direction during heating. The above described temperature gradient can nevertheless be achieved.

To allow proper control of the glass temperature by pyrometer it has been seen beneficial to cool the chamber walls so that all temperatures of the substrate neighbourhood are below substrate temperature except for the lamp heater.

A key factor for the deposition is the temperature of the substrate, since it directly influences the film thickness of the layer and therby the homogeneity of the films. As mentioned above the substrates are transferred to the first deposition chamber (PM) 2 already heated. In general it is desired to have uniform heat distribution on the substrate at the beginning of the deposition. For solar applications however is has been shown that it may be beneficial to have a non uniform temperature profile and consequently a non uniform thickness profile on the glass. For example a higher thickness of ZnO in the edge region is seen as an advantage for thin film solar cells. The degradation of boron doped ZnO layers is normally higher in the edge regions thus lowering the conductance of the thin film contact area over time. This increased degradation can thus be compensated by a higher edge layer thickness so that after time the overall resistance of the ZnO contact layer is uniform and below a required value of 15 Ohm square.

As decribed above, a heating plate 53 with individually heated border element 51 allows as well an adjusted, uniform temperature/coating profile as well as a non-uniform coating profile with increased layer thickness at edge regions of the substrate.

In one embodiment according to the present invention a three zone approach has been chosen. Two zones are located on a center plate of the hot plate 53; one zone, representatd by border element 51 is separated from the center plate and controlled thermally independently. The temperature of the center zone is about 175° C. whilst the edge zone is set to 190° C. This way the outer edge zone shall compensate or even overcompensate heat losses of the glass substrate to the surrounding area.

FIG. 3 shows a schematic drawing of a reactor/process module where the actual reaction takes place. A substrate 35 is placed on the heater table 34 (hot table). The (retractable) transport rollers 36 are shown as well as the gas shower assembly 37, 38. The gas shower assembly comprises two parts, a gas dosing part 37 and a gas distribution part 38 respectively.

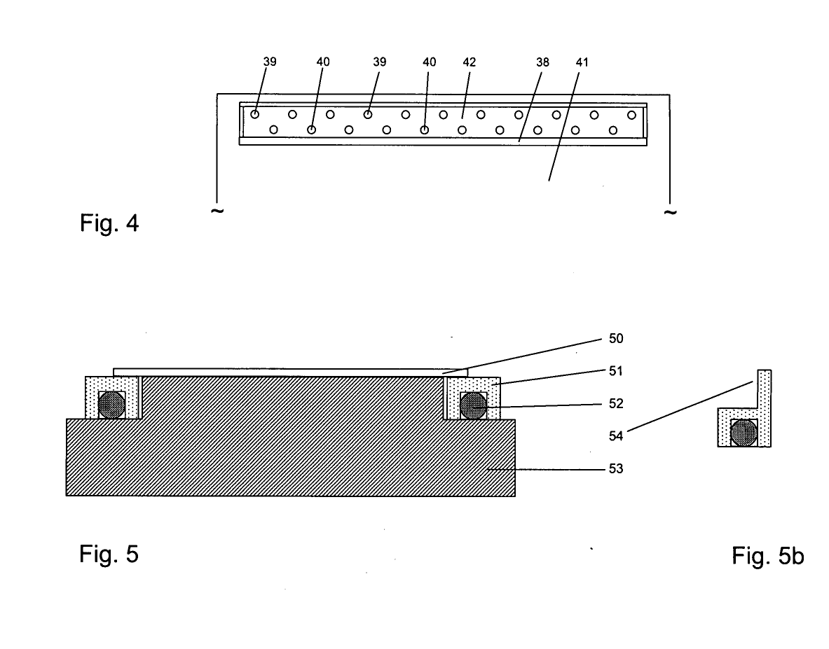

The gas dosing part is been displayed in more detail in FIG. 4 and comprises gas pipes with well defined holes where gas may flow into the process chamber (PM) 41. Maintaining a pressure in the PM 41 of about 0.5 mbar and having a flow through the gas dosing part of approximately 1-2 standard liter (1000-2000 sccm) gas flow results in a pressure in the gas dosing pipes between 5 mbar to 20 mbar. The gas dosing pipes are arranged in parallel to each other, supplying the gas mixing room 42 with gas in a homogeneous way. This is done by equally spaced holes in the gas dosing pipes 39, 40.

Two arrays of gas dosing pipes exist, one for water vapour 39 and one for DEZ and diborane 40.

The gas distribution part 38 is designed as gas shower plate and is distributing the gas over a well defined hole pattern to the specific areas of the substrate.

### SUMMARY

A method for depositing a thin film on a substrate in an inline vacuum processing system comprising the following steps:

a) introducing a first substrate into a load-lock chamber,

b) lowering the pressure in said chamber

c) transferring said first substrate into a first deposition chamber

d) depositing a layer of a first material at least partially on said first substrate using a first set of coating parameters

e) transferring said first substrate into a second, subsequent deposition chamber of said inline system without breaking vacuum

f) depositing a further layer of said first material at least partially on said first substrate using substantially the same set of paramaters

g) transferring said first substrate into a load lock chamber

h) removing said first substrate from said system and that simultaneously to step f) a second substrate is being treated in said inline vacuum system according to step d)

Embodiments of said Method will or may comprise:
Said first set of deposition paramaters comprising gas flow, chemical substances and pressure.
Said layer comprising a transparent conductive oxide
Said depositing comprising one of CVD, PECVD, LPCVD, PVD or reactive PVD.
Step b) comprising an additional heating step of the substrate
Said partial coating is deposited in equal 1/n parts of the desired overall thickness in said deposition chambers.
Said low pressure chemical vapour deposition is performed with pressure ranges between 0.3 and 1.1 mbar.
The material of said substrate is one of polymer, metal or glass.
Said substrate has the shape of a plate and lies horizontally during the whole process
Said plate-shaped substrate has a size of at least 1 m² and has a thickness between 0.3 m and 5 cm, preferably between 2 and 5 mm
Said TCO film on said substrate is a front-contact electrode for a solar cell
Said TCO film on said substrate is a back-contact electrode for a solar cell
Said TCO film is zinc oxide or tin oxide
Said method may use reactants like water in liquid or gaseous form, organometallic substances, for instance diethylzinc (dez) and diboran as dopant

An apparatus for the inline vacuum processing of substrates comprising
At least one one load-lock chamber,
At least two deposition chambers to be operated with essentially the same set of coating parameters,
At least one unload-lock chamber and
Means for transferring, post-processing and/or handling substrates through and in the various chambers

In further embodiments said apparatus will or may comprise
A load-lock chamber including heating means, pumping means for creating and maintaining vacuum conditions, means for substrate transport, as well as means to introduce gases, such as inert and/or working and/or deposition gases; heating means comprising an infrared-ray-module.
The load-lock chamber including a belt conveyor as a means for transport of the substrate; deposition chambers having means for substrate support during deposition, means for substrate transport, means to introduce the reactants necessary for deposition, vacuum pumps as well as heating means.
The means for substrate transport in the deposition chamber are internally-cooled retractable wheels or rollers ; the means for substrate support being vertically movable pins adapted to lift the substrate from the rollers
Means to introduce reactants necessary for deposition designed according to the shower-head principle
The unload-lock chamber including means for substrate transport and/or cooling and/or venting
The load-lock chamber having a substrate-entrance that is fed by a load station provided with transfer means for receiving substrates from at least a worker, a robot or another processing sytem
The chambers and the load and unload stations being arranged subsequently (like in a chain) in a straight-line so that underneath the chambers, post-processing means, namely back-transport means, moving in opposite direction respectively to the deposition process of the upper chambers, can be placed in order to further cool-down the processed substrates down to ambient temperature conditions eventually including cooling means within the footprints of the deposition process line.
The load station having a lift or elevator for lifting the processed substrate from the back-transport means in order to receive the coated substrate at a site where at least a worker or a machine can handle it and stock it apart.

1. A method for depositing a thin film on a substrate in an inline vacuum processing system comprising the following steps:
a) introducing a first substrate into a load-lock chamber (2),
b) lowering the pressure in said chamber
c) transferring said first substrate into a first deposition chamber (4)
d) depositing a layer of a first material at least partially on said first substrate using a first set of coating parameters
e) transferring said first substrate into a second, subsequent deposition chamber (5) of said inline system without breaking vacuum
f) depositing a further layer of said first material at least partially on said first substrate using substantially the same set of parameters
g) transferring said first substrate into a load lock chamber (10)
h) removing said first substrate from said system wherein simultaneously to step f) a second substrate is being treated in said inline vacuum system according to step d)

2. The method according to claim 1, wherein said first set of deposition parameters comprises gas flow, chemical substances and pressure.

3. The method according to claim 1, wherein said depositing includes one of CVD, PECVD, LPCVD, PVD or reactive PVD.

4. The method according to claim 1, wherein step b) comprises an additional heating step of the substrate.

5. The method according to claim 1, wherein said at least partially deposited layer is deposited in equal 1/n parts of the desired overall thickness in said deposition chambers.

6. The method according to claim 1, wherein said method may use reactants like water in liquid or gaseous form, organometallic substances like diethylzinc (dez) and diboran as dopant.

7. An apparatus for the inline vacuum processing of substrates comprising
At least one load-lock chamber (2),
At least two subsequent deposition chambers (4, 5) to be operated with essentially the same set of coating parameters,
At least one unload-lock chamber (10) and
Means for transferring, post-processing and/or handling substrates through and in the various chambers

8. Apparatus according to claim 7, the deposition chambers further comprising means for substrate transport, said means being retractable wheels or rollers (36) and being vertically movable pins adapted to lift the substrate from the rollers.

9. Apparatus according to claim 7, wherein the deposition chambers (4, 5) and the load and unload chambers (2, 10) are being arranged subsequently in a straight line and that underneath the chambers, back-transport means (21-26) are being arranged for moving substrates in opposite direction with respect to the deposition process of the upper chambers.

10. An apparatus according to claim 9, wherein the load station comprises a lift or elevator for lifting the processed substrate from the back-transport means in order to receive the coated substrate at a site where at least a worker or a machine can handle it and stock it apart.
